(19) United States
(12) Patent Application Publication
(10) Pub. No.: US 2015/0340501 A1
(43) Pub. Date: Nov. 26, 2015

(54) FORMING INDEPENDENT-GATE FINFET WITH TILTED PRE-AMORPHIZATION IMPLANTATION AND RESULTING DEVICE

(71) Applicant: GLOBALFOUNDRIES INC., Grand Cayman, KY (US)

(72) Inventors: Xusheng WU, Ballston Lake, NY (US); Johannes Marinus VAN MEER, Delmar, NY (US); Manfred ELLER, Beacon, NY (US); Vara Govindeswara Reddy VAKADA, Clifton Park, NY (US)

(73) Assignee: GLOBALFOUNDRIES INC., Grand Cayman, KY (US)

(21) Appl. No.: 14/285,042

(22) Filed: May 22, 2014

(51) Int. Cl. H01L 29/78; H01L 21/265; H01L 29/66

(52) U.S. Cl. CPC H01L 29/7849; H01L 29/7855; H01L 29/66795; H01L 29/66484; H01L 21/26586

(57) ABSTRACT

Methods for producing independent-gate FinFETs with improved channel mobility and the resulting devices are disclosed. Embodiments may include forming an independent-gate fin field-effect transistor (FinFET) above a substrate; and forming stress within the fin between two independent gates of the independent-gate FinFET.

### TECHNICAL FIELD

The present disclosure relates to independent-gate fin field-effect transistors (FinFETs). The present disclosure is particularly applicable to independent-gate FinFETs with improved performance for 20 nanometer (nm) technology nodes and beyond.

### BACKGROUND

Strain memorization technique (SMT) is one way to improve planar n-type field effect transistors (nFETs) in the 28 nm technology node. For planar technology, SMT improves performance by introducing tensile strain into the nFET channel. Because of the three-dimensional nature of FinFETs, however, stress has a canceling effect with the fin channel, and the stress cannot be introduced into the fin channel uniformly.

Current focus on multi-threshold voltage design within FinFETs utilizes multi-workfunction metal gates and/or aggressive channel implantation. Both of these approaches, however, result in highly complex processes and/or device performance degradation.

A variant of a double gate FinFET device in which the two gates are independent is an independent-gate FinFET. Independent-gate FinFETs include two isolated gates formed by removing the gate region joining the two gates on opposite sides of a fin. Although the two gates are isolated by removing the gate region at the top of the fin, the two gates' electrostatics are still coupled. The threshold voltage of either gate is influenced by applying an appropriate voltage to the other gate. Such a technology is also referred to as multiple independent-gate FET (MIGFET) and can be integrated with regular double-gate devices on the same chip.

For independent-gate FinFETs, the threshold voltage can be adjusted with back-gate voltage optimization. This offers dynamic or static performance tuning that gives chip designers greater flexibility. The back-gate voltage is used as an optimization knob that allows for high static random access memory (SRAM) yield. However, independent-gate FinFETs suffer from performance degradation compared to regular double-gate FinFETs because one of the independent gates is a body voltage control gate used to control body voltage.

A need, therefore, exists for independent-gate FinFETs with improved performance and a process for making the same.

### SUMMARY

An aspect of the present disclosure is a method for producing an independent-gate FinFET with improved channel mobility and performance

Another aspect of the present disclosure is an independent-gate FinFET with improved channel mobility and performance.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming a FinFET above a substrate; and forming stress within the fin between two independent gates of the independent-gate FinFET.

An aspect of the present disclosure includes the fin having a fin channel between the two independent gates, and the stress is formed within the fin channel. A further aspect of the disclosure includes forming the stress including: implanting a dopant at an oblique angle to the fin channel; forming an SMT capping layer over the independent-gate FinFET; annealing the SMT capping layer and the independent-gate FinFET; and removing the SMT capping layer. Another aspect includes implanting the dopant at the oblique angle to the fin channel to implant the dopant at a greater concentration on one side of the fin channel than another side of the fin channel. Yet another aspect includes the two independent gates being a main nFET gate and a body voltage control nFET gate, and the one side of the fin channel corresponds to the nFET main gate and the another side of the fin channel corresponds to the body control voltage nFET gate. A further aspect includes the stress relative to the main nFET gate being tensile stress. An additional aspect includes the two independent gates being a main pFET gate and a body voltage control pFET gate, and the one side of the fin channel corresponds to the body control voltage pFET gate and the another side of the fin channel corresponds to the pFET main gate. Yet another aspect includes the stress relative to the main pFET gate being compressive stress. A further aspect includes the dopant being one or more of silicon (Si), germanium (Ge), argon (Ar), xenon (Xe), difluoroboron (BF₂), arsenic (As), and indium (In). Still another aspect includes the annealing being one of a rapid thermal anneal (RTA), a millisecond thermal anneal (MSA), and a laser spike anneal (LSA).

Another aspect of the present disclosure is a device including: a substrate; fins above the substrate extending in a first direction; gates above the substrate extending in a second direction, perpendicular to the first direction, and intersecting with the fins, wherein top surfaces of the gates are co-planar with top surfaces of the fins, forming FinFETs, and the fins include fin channels between the gates, the fin channels having stress induced by pre-amorphization implantation (PAI) SMT.

Aspects include one side of the fin channels being implanted with a dopant at a greater concentration than another side of the fin channels. Another aspect includes the gates including a main nFET gate and a body voltage control nFET gate on opposite sides of one or more fin channels, with the main nFET gate is on the one side of the one or more fin channels and the body voltage control nFET gate is on the another side of the one or more fin channels. Yet another aspect includes the stress relative to the main nFET gate being tensile stress. Still another aspect includes the gates including a main pFET gate and a body voltage control pFET gate on opposite sides of one or more fin channels, with the main pFET gate being on the another side of the one or more fin channels and the body voltage control pFET gate being on the one side of the one or more fin channels. An additional aspect includes the stress relative to the main pFET gate being compressive stress. A further aspect includes the dopant being one or more of Si, Ge, Ar, Xe, BF₂, As, and In.

Another aspect of the present disclosure includes: forming a FinFET above a substrate, the independent-gate FinFET including a fin channel between a main gate and a body control voltage gate; performing PAI of a dopant in the fin channel at an oblique angle to the fin channel exposing one side of the fin channel more than another side of the fin channel to the dopant, generating stress within the fin channel; forming a SMT capping layer on the independent-gate FinFET with the doped fin channel; annealing the SMT capping layer and the independent-gate FinFET with the doped fin channel locking in the stress within the fin channel; and removing the capping layer.

A further aspect includes the one side of the fin channel facing the main gate and the other side of the fin channel facing the body control voltage gate, and the main gate and the body control voltage gate are nFETs. Still another aspect includes the one side of the fin channel facing the body control voltage gate and the other side of the fin channel facing the main gate, and the main gate and the body control voltage gate are pFETs.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 through 4 schematically illustrate a method for producing an independent-gate FinFET with improved channel mobility, in accordance with an exemplary embodiment; and

FIG. 5 schematically illustrates an independent-gate FinFET with improved channel mobility based on stress within the fin channel, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of poor performance attendant upon independent-gate FinFETs. In accordance with embodiments of the present disclosure, stress is induced within the fin channel of independent-gate FinFETs according to a tilted pre-amorphization implantation that increases channel mobility within the fin.

Methodology in accordance with an embodiment of the present disclosure includes forming an independent-gate FinFET above a substrate. Stress is then formed within the fin between two independent gates of the independent-gate FinFET.

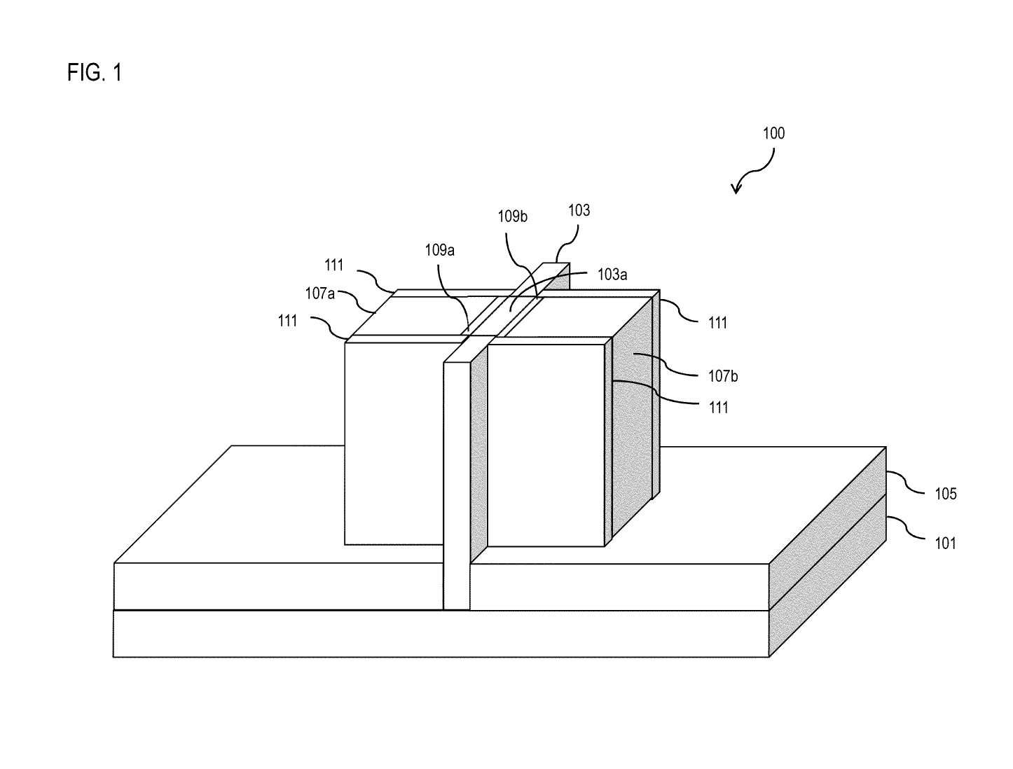

Adverting to FIG. 1, a method for producing an independent-gate FinFET with improved channel mobility, according to an exemplary embodiment, begins with an independent-gate FinFET 100 (hereinafter, FinFET 100). The FinFET 100 includes a substrate 101. The substrate 101 may be a bulk silicon substrate. Alternatively, the substrate 101 may be an elementary semiconductor, such as Si or Ge in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. Possible substrates 101 also include a silicon-on-insulator (SOI) substrate.

The FinFET 100 further includes a fin 103 formed above the substrate 101. Although only one fin 103 is illustrated in FIG. 1, it is understood that the FinFET 100 can include any number of fins. The fin 103 can be formed according to any suitable process for forming one or more fins, such as by etching the substrate 101 to form the fin 103.

The FinFET 100 also includes an isolation layer 105 formed on the substrate 101 to isolate active regions of the substrate 101. The isolation layer 105 utilizes isolation technology, such as shallow trench isolation (STI), to define and electrically isolate the various regions. The isolation layer 105 may be formed of silicon oxide (SiO), silicon nitride (SiN), silicon oxynitride (SiOₓN_{y}), or combinations thereof. The isolation layer 105 can be formed according to any suitable process.

The FinFET 100 includes two gate electrodes 107a and 107b above the substrate 101. The gate electrodes 107a and 107b can be formed above the substrate 101 according to any suitable process and can be formed of any suitable material, such as polysilicon (p-Si), aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminade (TiAl), titanium aluminum nitride (TiAlN), tantalum carbonitride (TaCN), tantalum carbide (TaC), tantalum silicon nitride (TaSiN), other suitable materials, and/or combinations thereof. The two gates electrodes 107a and 107b do not overlap the fin 103 because the FinFET 100 is an independent-gate FinFET, as described above. Further, the portion of the fin 103 that is between the gate electrodes 107a and 107b is a fin channel 103a.

The FinFET 100 further includes gate dielectrics 109a and 109b. The gate dielectrics 109a and 109b are formed of a dielectric material, such as SiO, SiN, SiOₓN_{y}, a high-k dielectric material, other suitable dielectric material, and/or combinations thereof.

The FinFET 100 also includes spacers 111 on opposite sides of the gate electrodes 107a and 107b and gate dielectric 109a and 109b. The spacers 111 may be formed of a dielectric material, such as SiN, SiO, SiOₓN_{y}, low-K dielectric materials, other suitable materials, and/or combinations thereof.

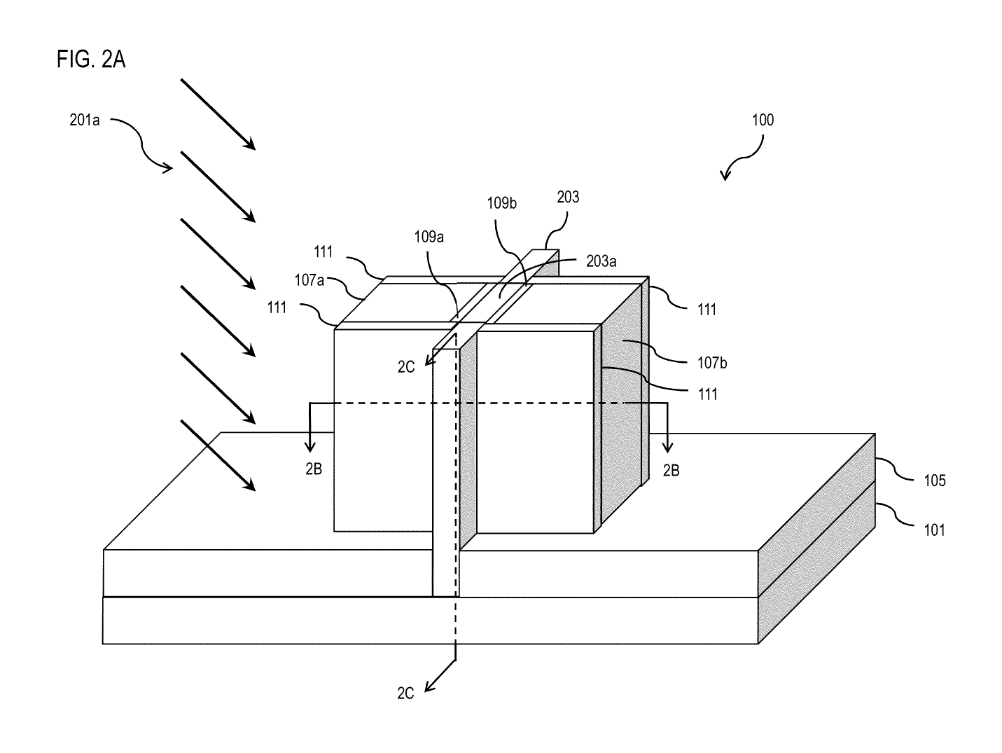

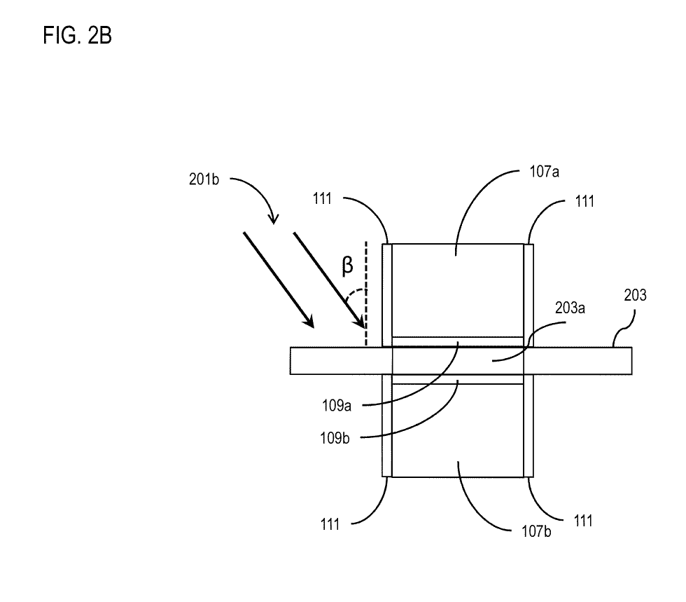

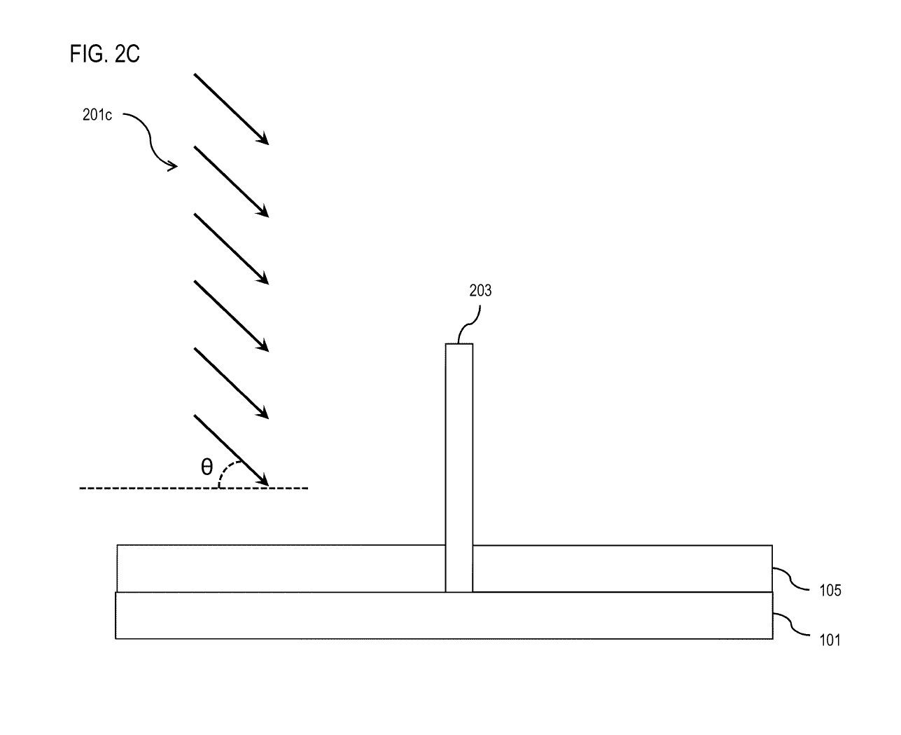

Adverting to FIG. 2A, the FinFET 100 undergoes a tilted PAI in which a dopant is implanted into the fin 103. The titled PAI dopes the fin 103 and the fin channel 103a, creating a doped fin 203 and doped fin channel 203a. The dopant can be one or more of Si, Ge, Ar, Xe, BF₂, As, and In. The PAI is tilted because the dopant is implanted at an angle to the fin 103, as generally represented by arrows 201a in FIG. 2A, particularly to the fin channel 103a between the gate electrodes 107a and 107b. As illustrated in FIGS. 2B and 2C, the tilt is within two planes, a horizontal plane along line 2B-2B and a vertical plane along line 2C-2C. As illustrated in FIG. 2B, the angle of tilt β of the implantation of the dopant represented by arrows 201b within the horizontal plane can be 0 to 89 degrees, such as 30 degrees. As illustrated in FIG. 2C, the angle of tilt θ of the implantation of the dopant represented by arrows 201c within the vertical plane can be 30 to 89 degrees, such as 75 degrees. By implanting the dopant at an angle with respect to the fin 103 and fin channel 103a, one side of the fin 203 and fin channel 203a is doped greater than the other side of the fin 203 and fin channel 203a. Specifically, the left side of the fin 203 and fin channel 203a illustrated in FIG. 2A are implanted with more dopant than the right side of the fin 203 and fin channel 203a Implanting the dopant creates an amorphous structure within the fin 203 and the fin channel 203a. The specifics of the amorphous structure are determined based on the conditions of the implantation, such as implant energy, implant dopant, implantation angle and/or implant dosage. Depending on the specifics of the PAI, the entire FinFET 100 or select portions of the FinFET 100 are also doped. However, for the purpose of this disclosure, the focus is on the fin 103 and the fin channel 103a being doped.

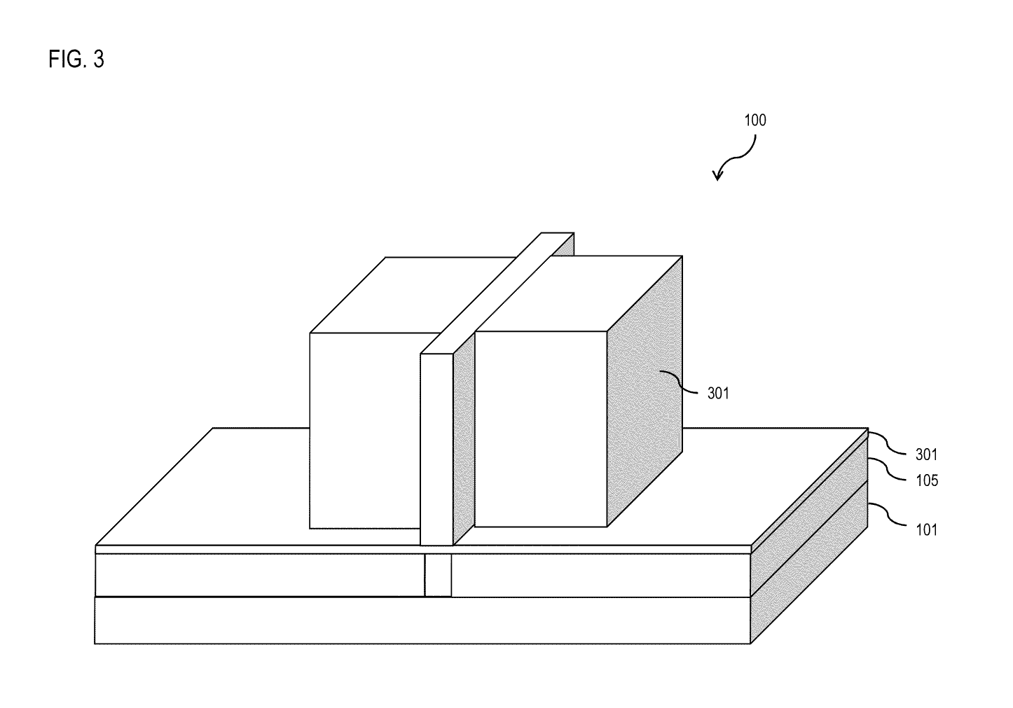

Next, a SMT capping layer 301 is formed over the FinFET 100, including the doped fin 203 and doped fin channel 203a, as illustrated in FIG. 3. The SMT capping layer 301 can be formed of SiN or other suitable materials, such as SiO₂, and can be formed to a thickness of 200 to 2000 Å. The SMT capping layer 301 can be formed according to any suitable process.

After forming the SMT capping layer 301, the SMT capping layer 301 and FinFET are annealed. The annealing causes the doped fin 203 and the doped fin channel 203a to revert to a crystalline form after becoming amorphous as a result of the implanted dopant. However, the annealing combined with the SMT capping layer 301 causes the doped fin 203 and doped fin channel 203a to retain the stress effects caused by the SMT capping layer 301 and from reverting from the amorphous state to the crystalline state. The annealing process re-crystallizes the amorphous regions created during the PAI.

The anneal can be one of an RTA, an MSA, and an LSA. Specifically, the annealing process can be applied to the FinFET 100 and the SMT capping layer 301 with an annealing temperature ranging between 200° C. and 1050° C. The annealing process can be from 5 to 30 seconds (s). The annealing process may optionally include a long range pre-heat that minimizes or eliminates end-of-range (EOR) defects. The conditions of the long range pre-heat can be 200° C. to 700° C. for 50 to 300 s.

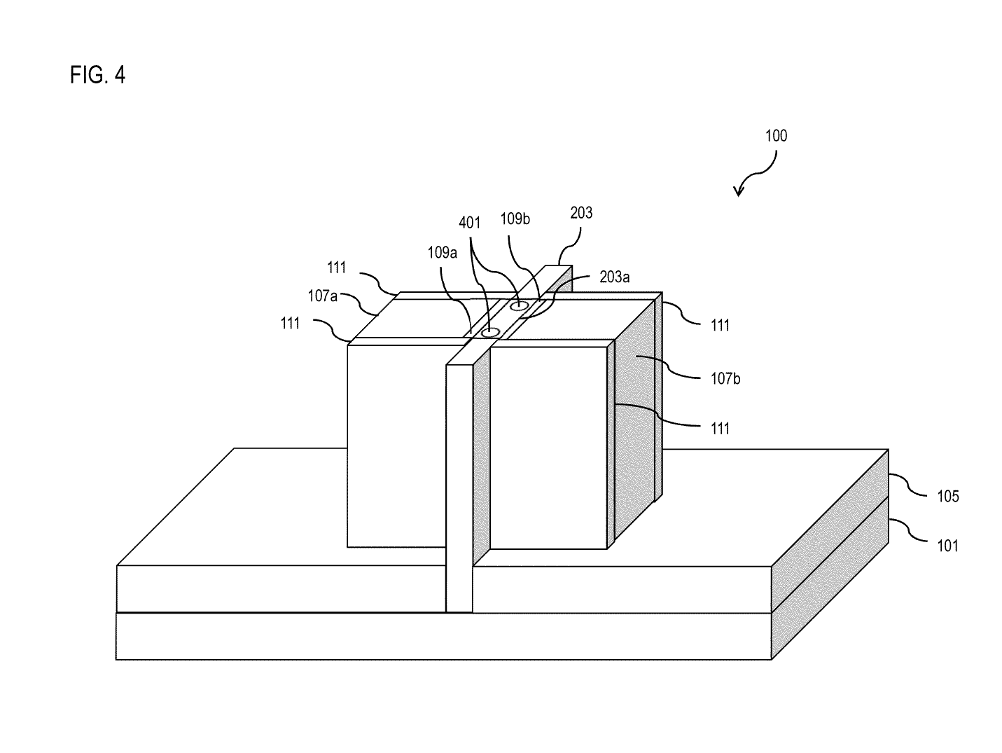

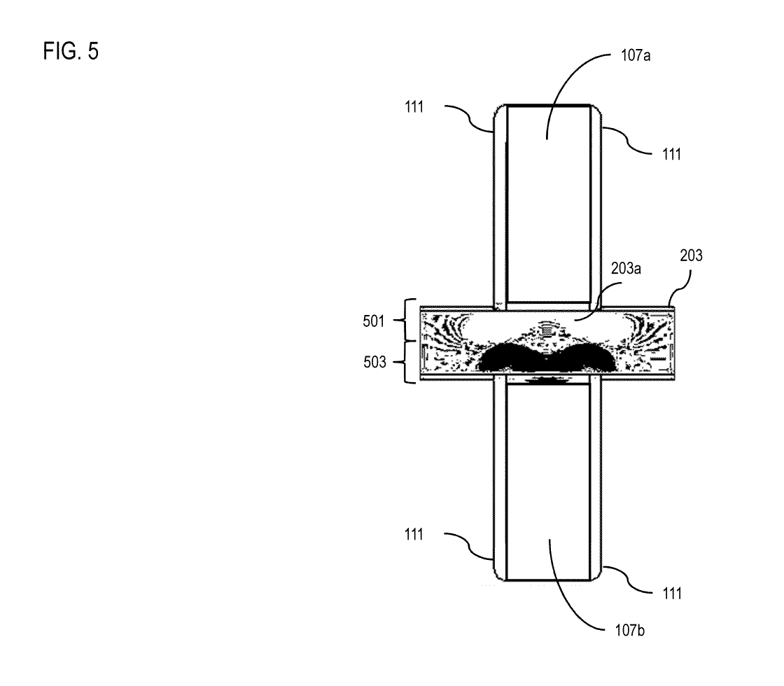

Adverting to FIG. 4, the SMT capping layer 301 is removed. The SMT capping layer 301 can be removed by a wet etching or a dry etching process, such as by phosphoric acid (H₃PO₄), hydrofluoric acid (HF), or buffered HF. Removing the SMT capping layer 301 reveals stress regions 401 in the doped fin channel 203a. The stress regions 401 include a tensile component and a compressive component because of the tilted PAI. Specifically, as illustrated in FIG. 5, the doped fin channel 203a includes a tensile stress region 501 and a compressive stress region 503. The tensile stress region 501 forms on the side of the fin channel 103a that is directly exposed to the dopant. The compressive stress region 503 forms on the side of the fin channel 103a that is not directly exposed to the dopant. The tensile stress within the tensile stress region 501 provides for better nFET mobility. Similarly, the compressive stress within the compressive stress region 503 provides for better pFET mobility. Thus, in forming an nFET independent-gate FinFET with two nFET gates, the side of the doped fin 203 and doped fin channel 203a that is directly exposed to the dopant because of the titled PAI corresponds to the main nFET gate because of the enhanced nFET mobility provided by the tensile stress region 501. In forming a pFET independent-gate FinFET with two pFET gates, the side of the doped fin 203 and doped fin channel 203a that is not directly exposed to the dopant because of the tilted PAI corresponds to the main pFET gate because of the enhanced pFET mobility provided by the compressive stress region 503. The other of the nFET gate and the pFET gate correspond to the body voltage control gates.

After the titled PAI, SMT, and removal of the SMT capping layer 301, the FinFET 100 may undergo further processing to form various features known in the art for FinFETs with no additional masks or lithography. Such processing may include removing portions of the fin 103/doped fin 203 to form raised source/drain regions on top of the fin 103/doped fin 203, in addition to the standard steps in manufacturing an independent-gate FinFET.

The embodiments of the present disclosure achieve several technical effects, including improved channel mobility and performance for nFET and pFET independent-gate FinFETs. The present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras, particularly for 20 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming an independent-gate fin field-effect transistor (FinFET) above a substrate; and
forming stress within the fin between two independent gates of the independent-gate FinFET.

2. The method according to claim 1, wherein the fin includes a fin channel between the two independent gates, and the stress is formed within the fin channel.

3. The method according to claim 2, wherein forming the stress comprises:
implanting a dopant at an oblique angle to the fin channel;
forming a strain memorization technique (SMT) capping layer over the independent-gate FinFET;
annealing the SMT capping layer and the independent-gate FinFET; and
removing the SMT capping layer.

4. The method according to claim 3, comprising:
implanting the dopant at the oblique angle to the fin channel to implant the dopant at a greater concentration on one side of the fin channel than another side of the fin channel.

5. The method according to claim 4, wherein the two independent gates comprise a main nFET gate and a body voltage control nFET gate, and the one side of the fin channel corresponds to the nFET main gate and the another side of the fin channel corresponds to the body control voltage nFET gate.

6. The method according to claim 5, wherein the stress relative to the main nFET gate is tensile stress.

7. The method according to claim 4, wherein the two independent gates comprise a main pFET gate and a body voltage control pFET gate, and the one side of the fin channel corresponds to the body control voltage pFET gate and the another side of the fin channel corresponds to the pFET main gate.

8. The method according to claim 7, wherein the stress relative to the main pFET gate is compressive stress.

9. The method according to claim 3, wherein the dopant is one or more of silicon (Si), germanium (Ge), argon (Ar), xenon (Xe), difluoroboron (BF₂), arsenic (As), and indium (In).

10. The method according to claim 3, wherein the annealing is one of a rapid thermal anneal (RTA), a millisecond thermal anneal (MSA), and a laser spike anneal (LSA).

11. An apparatus comprising:
a substrate;
fins above the substrate extending in a first direction;
gates above the substrate extending in a second direction, perpendicular to the first direction, and intersecting with the fins, wherein top surfaces of the gates are co-planar with top surfaces of the fins, forming independent-gate fin field-effect transistors (FinFETs), and the fins including fin channels between the gates, the fin channels having stress induced by pre-amorphization implantation (PAI) stress-memorization technique (SMT).

12. The apparatus according to claim 11, comprising:
one side of the fin channels being implanted with a dopant at a greater concentration than another side of the fin channels.

13. The apparatus according to claim 12, comprising:
the gates including a main nFET gate and a body voltage control nFET gate on opposite sides of one or more fin channels,
wherein the main nFET gate is on the one side of the one or more fin channels and the body voltage control nFET gate is on the another side of the one or more fin channels.

14. The apparatus according to claim 13, wherein the stress relative to the main nFET gate is tensile stress.

15. The apparatus according to claim 12, comprising:
the gates including a main pFET gate and a body voltage control pFET gate on opposite sides of one or more fin channels,
wherein the main pFET gate is on the another side of the one or more fin channels and the body voltage control pFET gate is on the one side of the one or more fin channels.

16. The apparatus according to claim 15, wherein the stress relative to the main pFET gate is compressive stress.

17. The apparatus according to claim 12, wherein the dopant is one or more of silicon (Si), germanium (Ge), argon (Ar), xenon (Xe), difluoroboron (BF₂), arsenic (As), and indium (In).

18. A method comprising:
forming an independent-gate fin field-effect transistor (FinFET) above a substrate, the independent-gate FinFET including a fin channel between a main gate and a body control voltage gate;
performing pre-amorphization implantation (PAI) of a dopant in the fin channel at an oblique angle to the fin channel exposing one side of the fin channel more than another side of the fin channel to the dopant, generating stress within the fin channel;
forming a strain memorization technique (SMT) capping layer on the independent-gate FinFET with the doped fin channel;
annealing the SMT capping layer and the independent-gate FinFET with the doped fin channel locking in the stress within the fin channel; and
removing the capping layer.

19. The method according to claim 18, wherein the one side of the fin channel faces the main gate and the other side of the fin channel faces the body control voltage gate, and the main gate and the body control voltage gate are nFETs.

20. The method according to claim 18, wherein the one side of the fin channel faces the body control voltage gate and the other side of the fin channel faces the main gate, and the main gate and the body control voltage gate are pFETs.
